(19) United States
(12) Patent Application Publication
(10) Pub. No.: US 2026/0117384 A1
(43) Pub. Date: Apr. 30, 2026

(54) CERAMIC HEATER ASSEMBLY WITH INTEGRATED STRESS RELIEF USEFUL IN THE FABRICATION OF MICROELECTRONIC DEVICES

(71) Applicant: Tokyo Electron Limited, Tokyo (JP)

(72) Inventor: Melvin Verbaas, Austin, TX (US)

(21) Appl. No.: 18/929,112

(22) Filed: Oct. 28, 2024

(51) Int. Cl. C23C 16/458; H05B 3/74

(52) U.S. Cl. CPC C23C 16/4586; H05B 3/74

(57) ABSTRACT

This substrate mounting stand for heating a semiconductor substrate comprises: a ceramic disc-shaped part that has a mounting surface on the upper surface thereof, said mounting surface being configured such that a semiconductor substrate can be mounted thereto; and a plurality of heating circuits that are respectively embedded in the disc-shaped part so as to extend parallel to the mounting surface within a plurality of regions delineated by partitioning the disc-shaped part into concentric circles when viewed from the mounting surface side. Among the plurality of heating circuits, an inner heating circuit is positioned closer to the mounting surface than an outer heating circuit is.

### FIELD OF THE INVENTION

The disclosure relates to microelectronic processing apparatuses and methods that incorporate a heated, ceramic support assembly for supporting and heating a microelectronic workpiece during heated processing, and more particularly to such apparatuses and methods in which the heated, ceramic support assembly includes a pedestal supporting an attached platen using stress relieving attachment strategies.

### BACKGROUND OF THE INVENTION

In the semiconductor manufacturing industry, ceramic heaters, also referred to herein as heated workpiece support modules are used in process chambers of processing tools to support microelectronic workpieces, during one or more stages of manufacture of corresponding microelectronic devices. The heated workpiece support modules play an important role in the thermal management of microelectronic workpieces during high-temperature processing operations. Such high-temperature process operations include Chemical Vapor Deposition (CVD), Plasma Enhanced Chemical Vapor Deposition (PECVD), and other high temperature processes discussed below. These heaters are specifically designed to support and heat microelectronic workpieces to the requisite temperatures that facilitate the deposition of thin films and other materials onto the workpiece surface. Made from high-performance ceramic materials such as aluminum nitride (AIN), silicon carbide (SiC), silicon nitride (Si₃N₄), and others, these heaters offer exceptional thermal conductivity, resistance to thermal shock, and chemical stability under the extreme conditions typical of semiconductor processing environments.

The adoption of ceramic heaters in semiconductor fabrication is largely due to their compatibility with the high-temperature requirements of processes like CVD and PECVD. These processes demand excellent temperature control and uniform heat distribution across the wafer surface to ensure the consistent quality and characteristics of the deposited layers. Ceramic heaters, with their high thermal conductivity and stability, are ideally suited to meet these requirements, providing the necessary environment for controlled film growth and material properties.

In a typical construction, a heated workpiece support module includes a ceramic heated platen supported on a ceramic pedestal. The heated platen is bonded to the pedestal via a bonding interface. Examples of background art in this field include U.S. Pat. Nos. 9,340,462 B2; 10,882,130 B2; 10,646,941 B2; 9,315,424 B2; and 9,556,074 B2; U.S. Pat. Pub. No. 2014/0197227 A1; Japan Patent Documents JP 2019/031434 A; JP 59-51791 B2; JP 2015/505806 A; and JP 63-70062 B2; PCT Pat. Pub. No. WO2013/082564 A2; and Korea Patent Documents KR 102226887 B1; KR 101944501 B1; KR 20200019235 A; KR 20160122856 A; and KR 20190079114 A.

In some embodiments, the pedestal is hollow. The interior volume of the hollow pedestal may provide an egress to the backside of the platen for routing or deploying electrical components, sensors, and the like. In such embodiments, it is desirable to maintain a vacuum tight seal between the platen and the pedestal to avoid contamination or otherwise compromising the integrity of the process chamber during treatments. This is challenging during high temperature processing, because thermal and mechanical stresses can challenge the integrity of the bond and, therefore, the integrity of the vacuum tight seal.

In some embodiments, which may include hollow or solid pedestals, metal or other components, such as metal rods or wiring, may be embedded in the pedestal, including at the attachment interface between the pedestal and the platen, in order to help provide electric coupling to electrical connects or wiring of the platen. Due to differences in the coefficient of thermal expansion between the ceramic materials of the heated workpiece support module and the metal components, mechanical and thermal stresses can develop during high temperature processes that challenge the integrity of the bond of the platen to the pedestal.

In view of these challenges, the industry desires improved strategies for attaching platens and pedestals together with an improved ability to help maintain the integrity of the attachment during high temperature processes. Strategies for improved attachment of platen to pedestal are needed for heated workpiece support modules that include a hollow pedestal and/or incorporate metal components that can challenge the integrity of the attachment.

### SUMMARY OF THE INVENTION

The present invention relates to microelectronic processing apparatuses and methods that incorporate a heated, ceramic support assembly for supporting and heating a microelectronic workpiece during heated processing, and more particularly to such apparatuses and methods in which the heated, ceramic support assembly includes a pedestal supporting an attached platen using thermal and mechanical stress relieving attachment strategies. The strategies help to maintain the integrity of the attachment of platen to pedestal during high temperature processes in process chambers in which processing is carried out. In those embodiments including a hollow pedestal, the strategies provide attachment strategies for maintaining a vacuum tight seal between the processing chamber and the interior volume of the pedestal.

In one aspect, the present invention relates to a heated workpiece support module useful to support a microelectronic workpiece in a process chamber during a process, said heated workpiece support module having a z-axis and comprising:
a) a heated platen having a top and a backside, wherein the workpiece is supported over the top of the platen during the process;
b) a hollow pedestal, wherein:
   1) the hollow pedestal is attached to the backside of the heated platen;
   2) the hollow pedestal contains an interior volume;
   3) the hollow pedestal is attached to the heated platen by a plurality of bonding interfaces that are configured to create a vacuum tight seal between the heated platen and the hollow pedestal, said plurality of bonding interfaces including:
      i) a first, continuous bonding zone that surrounds the interior passageway and that attaches the heated platen to the hollow pedestal proximal to the interior passageway; and
      ii) a second, independent, separate and continuous bonding zone that surrounds the interior volume and that attaches the heated platen to the hollow pedestal distal from the interior passageway, wherein at least a major portion of the second, independent, separate, and continuous bonding zone is separated from the first, continuous bonding zone by a bond-free zone; and
wherein at least a first interface portion of the first, continuous bonding zone is at a different z-height on the z-axis relative to at least a first interface portion of the second, continuous bonding zone.

In another aspect, the present invention relates to a heated workpiece support module useful to support a microelectronic workpiece during a process, said heated workpiece support module having a z-axis and comprising:
a) a heated platen having a top and a backside, wherein the workpiece is supported over the top of the platen during the process, wherein the heated platen comprises at least one annular ring projecting from the backside, and wherein the ring has a bottom;
b) a hollow pedestal having a top, wherein the top comprises at least one annular socket having a bottom sized and positioned to receive the annular ring of the heated platen, and, wherein:
   1) the hollow pedestal is attached to the backside of the heated platen;
   2) the hollow pedestal contains an interior volume;
   3) the hollow pedestal is attached to the heated platen by a plurality of bonding interfaces that are configured to create a vacuum tight seal between the heated platen and the hollow pedestal, said plurality of bonding interfaces including:
      i) a first bonding zone that surrounds the interior passageway and that attaches the heated platen to the hollow pedestal proximal to the interior passageway; and;
      ii) a second, annular bonding zone that is independent and separate from the first annular bonding zone and that bonds the bottom of the ring to the bottom of the socket in a manner such that a z-axis, gap is provided between the ring and the socket, wherein the gap has a height dimension extending along the z-axis.

In another aspect, the present invention relates to an apparatus useful to subject a microelectronic workpiece to a process, said apparatus comprising:
a) a housing defining a process chamber;
b) a heated workpiece support module having a z-axis and comprising:
   1) a heated platen having a top and a backside, wherein the workpiece is supported over the top of the platen during the process;
   2) a hollow pedestal, wherein:
      i) the hollow pedestal is attached to the backside of the heated platen;
      ii) the hollow pedestal contains an interior volume;
      iii) the hollow pedestal is attached to the heated platen by a plurality of bonding interfaces that are configured to create a vacuum tight seal between the heated platen and the hollow pedestal, said plurality of bonding interfaces including a first, continuous bonding zone that surrounds the interior passageway and that attaches the heated platen to the hollow pedestal proximal to the interior passageway; and a second, independent, separate and continuous bonding zone that surrounds the interior volume and that attaches the heated platen to the hollow pedestal distal from the interior passageway, wherein at least a major portion of the second, independent, separate, and continuous bonding zone is separated from the first, continuous bonding zone by a bond-free zone; and
   wherein at least a first interface portion of the first, continuous bonding zone is at a different z-height on the z-axis relative to at least a first interface portion of the second, continuous bonding zone

In another aspect, the present invention relates to an apparatus useful to subject a microelectronic workpiece to a process, said apparatus comprising:
a) a housing defining a process chamber;
b) a heated workpiece support module having a z-axis and comprising:
   1) a heated platen having a top and a backside, wherein the workpiece is supported over the top of the platen during the process, wherein the heated platen comprises at least one annular ring projecting from the backside, and wherein the ring has a bottom;
   2) a hollow pedestal having a top, wherein the top comprises at least one annular socket having a bottom sized and positioned to receive the annular ring of the heated platen, and, wherein:
      i. the hollow pedestal is attached to the backside of the heated platen;
      ii. the hollow pedestal contains an interior volume;
      iii. the hollow pedestal is attached to the heated platen by a plurality of bonding interfaces that are configured to create a vacuum tight seal between the heated platen and the hollow pedestal, said plurality of bonding interfaces including a first bonding zone that surrounds the interior passageway and that attaches the heated platen to the hollow pedestal proximal to the interior passageway; and a second, annular bonding interface that is independent and separate from the first annular bonding interface and that bonds the bottom of the ring to the bottom of the socket in a manner such that a z-axis, gap is provided between the ring and the socket, wherein the gap has a height dimension extending along the z-axis.

### BRIEF DESCRIPTION OF THE DRAWINGS

FIG. 1 schematically shows an illustrative microelectronic processing apparatus incorporating principles of the present invention.

FIG. 2 shows a schematic side view of a heated workpiece support module used in the apparatus of FIG. 1, wherein the heated workpiece support module incorporates principles of the present invention.

FIG. 3 shows a top schematic view of the platen used in the heated workpiece support module of FIG. 2.

FIG. 4A schematically shows a side cross-section view of the heated workpiece support module of FIG. 2 in a right side up orientation, wherein the heated workpiece support module includes a platen supported on a pedestal, and wherein the platen is attached to the pedestal via a bonding interface.

FIG. 4B schematically shows a side cross-section view of the platen and pedestal of the heated workpiece support module of FIG. 4A in an upside down orientation useful to bond the platen to the pedestal.

FIG. 5 shows a top view of the pedestal used in the heated workpiece support module of FIG. 4.

FIG. 6 shows a side cross-section view of the pedestal and bonding interface of FIG. 4.

FIG. 7 schematically shows a side cross-section view of the heated workpiece support module of FIG. 4 with an alternative embodiment of a bonding interface to connect the pedestal to the platen.

FIG. 8 shows a side cross-section view of the pedestal and bonding interface of FIG. 7.

FIG. 9 shows an alternative embodiment of a heated workpiece support module of the present invention, wherein the heated workpiece support module includes a platen supported on a pedestal in which annular ribs on the platen fit into corresponding annular sockets in the pedestal, and wherein the platen is attached to the pedestal via a bonding interface between the rings of the platen and the sockets of the pedestal.

FIG. 10 is a top view of the pedestal of FIG. 9.

FIG. 11 is a bottom view of the platen of FIG. 9.

FIG. 12 schematically illustrates an example of a texture that may be used to enhance bonding between the pedestal and platen in any of the embodiments of the heated workpiece modules of the present invention.

FIG. 13 schematically illustrates an example of an alternative form of a texture that may be used to enhance bonding between the pedestal and platen in any of the embodiments of the heated workpiece modules of the present invention.

FIG. 14 schematically illustrates an example of an alternative form of a texture that may be used to enhance bonding between the pedestal and platen in any of the embodiments of the heated workpiece modules of the present invention.

### DETAILED DESCRIPTION OF PRESENTLY PREFERRED EMBODIMENTS

The present invention will now be further described with reference to the following illustrative embodiments. The embodiments of the present invention described below are not intended to be exhaustive or to limit the invention to the precise forms disclosed in the following detailed description. Rather a purpose of the embodiments chosen and described is so that the appreciation and understanding by others skilled in the art of the principles and practices of the present invention can be facilitated.

The present invention provides apparatus embodiments and associated methods for performing one or more processes on microelectronic workpieces in the research, development, and fabrication of microelectronic devices such as integrated circuits (ICs), MEMS, sensors, and other electronic components. Several high-temperature processes are used to deposit materials with the aim of creating thin films, other layers, or structures on semiconductor wafers. The apparatus embodiments and methods of the present invention are particularly applicable for use in conjunction with high temperature processing of semiconductor workpieces such as high temperature deposition processes wherein a microelectronic workpiece being processed is heated to temperatures greater than about 80° C., greater than about 100° C., greater than about 200° C., greater than about 300° C., greater than 400° C., or greater than 550° C., such as from 80° C. to about 800° C., or 100° C. to about 800° C., or 300° C. to about 800° C.

Examples of such processes in which the practice of the present invention is useful include chemical vapor deposition (CVD), such as plasma-enhanced chemical vapor deposition (PECVD). Chemical Vapor Deposition (CVD) is a widely used material deposition process in the fabrication of microelectronic devices, thin films, and coatings. This technique involves the chemical reactions of gaseous precursors on or near the surface of a heated substrate, leading to the deposition of a solid material. The basic principle behind CVD is to introduce one or more volatile precursors into a reaction chamber, where these precursors undergo a thermal decomposition, react with each other, or react with the surface of the substrate at elevated temperatures to form a solid material that coats the substrate. CVD can be conducted under a range of pressures, including from atmospheric pressure (APCVD) to reduced pressures (LPCVD). The choice of process conditions, including temperature, pressure, and types of precursors, influences the properties of the deposited film, such as its composition, purity, morphology, and adhesion to the substrate.

CVD is versatile in terms of the materials it can deposit, including metals, semiconductors, dielectrics, and polymers. It is favored for its ability to produce high-quality, uniform films over large areas and complex shapes. The process is useful in various applications, such as where it is used to deposit gate oxides, insulating layers, conductive films, and various other structural layers of integrated circuits or other microelectronic devices.

The present invention is useful with respect to processes involving Plasma Enhanced Chemical Vapor Deposition (PECVD). PECVD is a variation of Chemical Vapor Deposition (CVD). PECVD uses plasma to enhance the chemical reaction rates of the gaseous precursors, sometimes at lower temperatures compared to conventional CVD methods. In PECVD, the substrate on which the film is to be deposited is placed inside a reaction chamber, and gases are introduced. A plasma is then generated in the chamber using RF (radio frequency) power, microwave power, or other plasma sources. The energetic ions and radicals generated in the plasma enable the chemical reactions that lead to the deposition of the solid material onto the substrate.

One advantage of PECVD over traditional CVD is the ability of PECVD to deposit various types of films at relatively lower temperatures, such as from about 100° C. to about 350° C., although higher temperatures may be used. The lower temperature processing may be beneficial for applications involving temperature-sensitive substrates, such as plastic films or previously deposited layers that might degrade or diffuse at higher temperatures.

Like CVD generally, PECVD is widely used in the fabrication of microelectronic and optoelectronic devices for depositing thin films such as silicon oxide, silicon nitride, amorphous silicon, and various organic and inorganic materials. The films deposited by PECVD are used for a variety of purposes, including dielectric layers, passivation layers, insulating barriers, and anti-reflective coatings, among others. PECVD offers good uniformity, conformal coating over complex geometries, and the ability to precisely control the composition and properties of the deposited films.

In addition to CVD and PECVD, the following are additional high-temperature deposition processes in which the practice of the present invention is useful:

Atomic Layer Deposition (ALD) is a vapor phase technique used for thin film growth that relies on the sequential use of a gas phase chemical process. ALD is known for its excellent conformality and control at the atomic scale, allowing for the precise deposition of nanometer-thick films. Although ALD can be performed at lower temperatures compared to traditional CVD, some ALD processes require high temperatures to achieve certain material qualities.

Molecular Beam Epitaxy (MBE) is a high-vacuum process used in applications such as for the epitaxial growth of crystalline layers. MBE allows atoms or molecules to be evaporated from a source and to condense on a substrate, forming thin films. This process often operates at high temperatures to ensure the mobility of adatoms on the substrate surface, enabling the growth of high-purity epitaxial layers.

Metalorganic Chemical Vapor Deposition (MOCVD), a type of CVD, uses metalorganic precursors for the deposition of thin films. MOCVD is widely used in the production of compound semiconductors and is particularly important in the fabrication of light-emitting diodes (LEDs) and semiconductor lasers. High temperatures are used to decompose the metalorganic compounds and to promote film growth on the substrate.

Sputtering, although not always considered a high-temperature process, may involve elevated substrate temperatures to improve film quality. Sputtering is a physical vapor deposition (PVD) process where atoms are ejected from a solid target material and then deposited on a substrate. Heating the substrate during deposition can enhance the mobility of atoms, leading to better film properties.

Thermal Evaporation (TEPVD) is a type of PVD process in which material from a thermal source is evaporated in a vacuum and then deposited on a substrate. The process can involve high temperatures to vaporize the source material, especially for materials with high melting points.

Rapid Thermal Processing (RTP), although often not practiced as a deposition process per se, is a heat treatment technique used to quickly heat and cool substrates. It is often used to anneal or activate dopants after ion implantation, drive in dopants after diffusion processes, or to change the properties of deposited films. High temperatures may be achieved rapidly to minimize unwanted diffusion in other regions of the device.

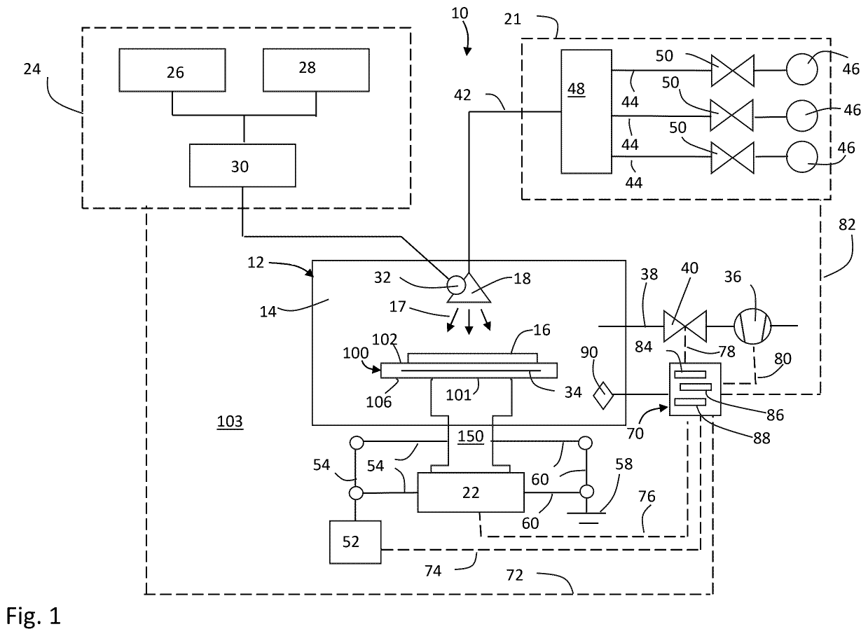

For purposes of illustration, the principles of the present invention will be described with respect to the PECVD apparatus 10 schematically shown in FIGS. 1 through 6. As seen best in FIG. 1, apparatus 10 includes housing 12 defining process chamber 14. Process chamber 14 serves to contain plasma 17 in the process chamber 14 during a plasma treatment of workpiece 16 supported on heated workpiece support module 20. For illustrative purposes, plasma 17 is generated by converting one or more process fluids, e.g., one or more kinds of gases and/or gas clusters in some embodiments, into the plasma 17. The one or more process fluids are dispensed into the process chamber 14 through a fluid dispensing unit in the form of showerhead module 18. The one or more process fluids are supplied to the showerhead module 18 from process fluid source system 21.

Lifting apparatus 22 includes components that can be actuated to help raise and lower heated workpiece support module 20. For example, heated workpiece support module 20 may be raised or lowered, as the case may be, to position the platen 100 in a suitable position to load and unload workpiece 16 through a suitable port (not shown). Heated workpiece support module 20 may be raised or lowered to position the workpiece 16 in one or more suitable positions to carry out the desired process. In some instances, the position of heated workpiece support module 20 may be adjusted as a process proceeds. In one illustrative embodiment, lifting apparatus 22 may include a bellows (not shown) that can be expanded or contracted to raise and lower heated workpiece support module 20.

At least one RF generator system 24 is operable to provide RF energy into a processing zone above workpiece 16 in the process chamber 14. The RF energy is used to convert at least a portion of the one or more process fluids into plasma 17. The RF generator system 24 includes a high-frequency generator 26 and/or a low-frequency generator 28, a matching network 30, an upper RF electrode 32 integrated into the fluid dispensing showerhead module 18, and a lower RF electrode 34 embedded in the heated workpiece support module 20 that supports the workpiece 16 during a plasma treatment. In a typical mode of operation of system, the high-frequency generator 26 and/or low-frequency generator 28 supply RF power to the electrodes 32 and 34. The matching network 30 helps to ensure that the impedance between the generators 26 and 28 and the electrodes 32 and 34 is properly aligned to help facilitate the transfer of RF energy to the one or more process fluids and thereby generate the plasma 17.

In one illustrative mode of practice, both the high-frequency RF generator 26 and the low-frequency RF generator 28 are used. In alternate modes of practice, just the high-frequency RF generator 26 is used. In other modes of practice, only the low-frequency RF generator 28 is used.

When energized by the RF power, in illustrative modes of practice the upper RF electrode 32 and lower RF electrode 34 cooperatively function to help ionize the one or more dispensed fluids. Typically, upper RF electrode 32 is energized by the RF power while the lower RF electrode 34 preferably is grounded during processing such as being coupled to ground contact 58, However, in an alternate embodiment, the lower RF electrode 34 also may be supplied with RF energy during processing. The interaction between the electrodes 32 and 34 helps to create an electric field in the space between the electrodes 32 and 34 whose energy helps to form the plasma 17 from the dispensed one or more process fluids. As the one or more process fluids are dispensed, the electric field generated by the RF electrodes ionizes the one or more fluids, converting these into plasma 17. This plasma 17 is then used to treat the surface of the microelectronic workpiece 16 to carry out a desired treatment such as etching, deposition, surface modification, or the like. An advantage of plasma treatments is that these can be carried out with high precision and excellent control.

The ability to use both high and low frequencies allows for fine-tuning of the plasma characteristics, thereby enhancing the effectiveness of the treatment process for different microelectronic applications. In illustrative embodiments, the high-frequency RF generator 26 may be operated at frequencies of about 2 MHz to about 100 MHz; or preferably from about 10 MHz to about 30 MHz e.g., such as 13.56 MHz or about 27 MHz In illustrative embodiments, the low-frequency RF generator 28 may be operated at about 50 kHz to 2 MHz; preferably at about 350 kHz to about 600 kHz.

In illustrative modes of practice, the plasma process desirably is performed under vacuum. Exhaust or vacuum functionality may help to remove byproducts and to maintain the desired pressure(s) within process chamber 14. Such functionality also may help to prevent contamination on workpiece 16 by evacuating materials from the process chamber 14. As one example of a strategy to provide vacuum conditions in process chamber 14, vacuum pump 36 helps to establish a vacuum through vacuum line 38. Vacuum valve 40 helps to control egress of withdrawn vapor, gas, gas clusters, plasma, or other fluids to be evacuated into vacuum line 38.

The one or more process fluids are introduced from a process fluid source system 21 to showerhead module 18 via supply line 42. In an embodiment, process fluid source system 21 includes one or more fluid sources 46. For purposes of illustration, three fluid sources 46 are shown. In some embodiments, only one or two fluid sources 46 may be used. In other embodiments, four or more fluid sources 46 may be used. The fluid material from multiple fluid sources 46 may be supplied to showerhead module 18 singly or in combination. If supplied in combination, multiple fluids may be pre-mixed upstream from showerhead module 18 and dispensed into process chamber 14 as a mixture. The mixture may be a physical blend of the fluids. Alternatively, the mixture may include products from a chemical reaction of the fluids. Alternatively, each fluid material can be separately introduced into process chamber 14 in some embodiments. As shown, corresponding supply lines 44 fluidly couple the fluid sources 46 to a manifold 48 to allow pre-mixing upstream from showerhead module 18. Appropriate valving and mass flow control mechanisms schematically shown as valves 50 are used to help ensure that the correct fluid materials in desired amounts are delivered to the showerhead module 18 during workpiece processing.

Power supply 52 is used to supply electrical power to heated workpiece support module 20 and lifting apparatus 22 via electrical supply lines 54. Desirably, apparatus 10 incorporates suitable RF shielding and grounding. Generally, RF shielding and electrical grounding help to contain the RF energy within the apparatus 10 and help prevent the RF energy from unduly affecting external devices or impacting operator safety. Accordingly, heated workpiece support module 20 and lifting apparatus 22 are coupled to ground contact 58 by electrical grounding lines 60.

A control system 70 is used to help control and optimize processes such as plasma enhanced chemical vapor deposition (PECVD) processes. Control system 70 incorporates one or more types of functionality to help control one or more of process implementation and/or monitoring, control, workpiece loading and unloading, supply monitoring, refill, servicing, processing and/or other apparatus operations. In illustrative embodiments, control system 70 includes computer processor 84, interface 86, memory 88, and information harvesting system 90. The control system 70 desirably allows for real-time monitoring and adjustments to help ensure the quality and consistency of the treatment(s) being carried out.

Communication connections of the control system 70 to other components of apparatus 10 may be wired and/or wireless. The other components may be local and/or remote, such as being cloud-based. For example, control system 70 communicates with RF generator system 24 via communication pathway 72. Control system 70 communicates with power supply 52 via communication pathway 74. Control system 70 communicates with lifting apparatus 22 via communication pathway 76. Control system 70 communicates with vacuum valve 40 via communication pathway 78. Control system 70 communicates with vacuum pump 36 via communication pathway 80. Control system 70 communicates with fluid source(s) 21 via communication pathway 82.

The control system 70 may use analog and/or digital communication strategies with respect to the communication pathways 72, 74, 76, 78, 80, and 82. For example, signals for monitoring the process may be harvested and then communicated by information harvesting system 90 by analog and/or digital input communications The signals for controlling the process also may be transmitting using analog and/or digital strategies.

Control system 70 may use information harvesting system 90 to gather information from apparatus 10, the ambient 103, and/or the like to allow for control functions such as real-time monitoring and adjustments during apparatus operation. Control system 70 may use information harvesting system 90 to harvest process information from a wide variety of locations within and external to apparatus 10. Examples of components useful in information harvesting system 90 include one or more of the following: sensors to detect the presence, absence, and position of workpiece 16; sensors to detect the status of each valve, pressure sensors to monitor the pressure inside the PECVD process chamber or supply lines; fluid flow sensors to measure the flow rates of the supplied fluid materials; temperature sensors to monitor the platen, workpiece, supplied fluid materials, and other componentry; plasma diagnostics tools, such as Langmuir probes or optical emission spectroscopy (OES) sensors, to analyze plasma properties (e.g., including density, temperature, and species composition); optical sensors for purposes such as in-situ film thickness measurement and monitoring the uniformity of the film being deposited; mass spectrometers such as to analyze the gas phase reactions and the composition of the plasma; infrared sensors to monitor temperatures such as on the workpiece, platen, and/or the substrate and chamber wall temperatures; humidity sensors such as to measure the moisture level in the chamber; imaging devices, such as high-resolution cameras or scanning electron microscopes (SEM) for surface analysis and defect inspection; electrical property measurement devices such as to assess the electrical properties of the deposited films, such as conductivity, resistivity, or capacitance, using in-situ or ex-situ techniques; sensors to monitor time; sensors to monitor process step initiation, progress, and completion; and/or the like. Information harvesting system 90 also may include sensors and diagnostic tools to monitor plasma characteristics such as density, temperature, and uniformity. The data collected may be used to adjust the RF power or gas flow in real-time, to help implement treatment conditions, and the like.

Typically, there will be at least one user interface 86 associated with control system 70. The user interface 86 may include a display screen, graphical software displays of the apparatus and/or process conditions, and user input devices such as pointing devices, keyboards, touch screens, microphones, combinations of these, and the like. Control interface 86 allows operators to select process recipes, set and carry out process parameters, monitor system performance, perform service and maintenance, and make adjustments as desired.

A transitory and/or non-transitory computer machine-readable medium can comprise program instructions for control of the apparatus 10. The computer program code for controlling the processing operations can be written in any conventional computer readable programming language. Compiled object code or script is executed by the computer processor 84 to perform the tasks identified in the program.

A process may be carried out following a computer executable instructions that cause execution of the process according to a recipe stored in a memory 88 and/or input or selected by a user. Memory 88 may store a plurality of different recipes that are selectable on demand. The user may customize recipe features using interface 86.

A variety of control strategies may be used to help control temperature of the heated workpiece support module 20 and workpiece 16. For example, feedback and/or feedforward strategies using proportional, integral, and/or derivative control, optionally with artificial intelligence functionality, can be used to sense information indicative of temperature and to independently increase or decrease the heat output of any of the backside heater 206 or heater elements 202 described below. In addition to directly measuring temperature in various heating zones, other characteristics can be monitored and used for temperature control of platen 100 and correspondingly the workpiece 16, such as the thickness of the film being deposited. For example, if the thickness is too thin in a heating zone, and if thickness inversely correlates to temperature, the temperature in the zone can be increased. If the thickness is too thick in a heating zone, and if thickness inversely correlates to temperature, the temperature in the zone can be decreased.

The heated workpiece support module 20 includes a platen 100 supported on pedestal 150. The pedestal 150 is attached to backside 106 of the platen 100. The pedestal 150 and platen 100 are coupled together at a bonding interface 101. Strategies of the present invention are useful to help improve the quality of the bonding interface 101. The strategies of the present invention include an improved ability of interface 101 to withstand thermal stresses and also to help retain a vacuum tight seal between the heated platen 100 and the pedestal 150, between the process chamber 14 and the interior volume 180 (described below) of the pedestal 150, and/or between the ambient 103 outside apparatus 10 and the interior volume 180 of pedestal 150.

During a treatment, such as a PECVD treatment, the platen 100, and correspondingly workpiece 16 supported over the platen 100, are heated to temperatures greater than about 80° C., greater than about 100° C., greater than about 200° C., greater than about 300° C., greater than about 400° C., or greater than about 550° C., such as from about 80° C. to about 800° C., or about 100° C. to about 800° C., or about 300° C. to about 800° C.

The platen 100 includes a top or processing side 102 over which the workpiece 16 is supported, a backside 106, outer periphery 107, and a platen body 116. Platen body 116 includes central region 118 in the volume of platen 100 proximal to the centrally located z-axis 104. The platen 100 includes the lower RF electrode 34 embedded therein. The backside 106 includes a centrally located socket 108 having a socket floor 110 and a socket sidewall 112. The socket 108 is sized for receiving a correspondingly sized annular boss 168 of the pedestal 150 when the platen 100 and pedestal 150 are attached together. Annular boss 168 is sized to fit with a substantially matching fit into the socket 108 on the backside 106 of platen 100. The boss 168, however, should be undersized relative to socket 108 so that there would be a gap between the walls of socket 108 and boss 168 if there was no bonding media present to create the bonding interface 101. In the present embodiment, the gap between the platen 100 and mating portions of the pedestal 150 are filled by the bonding media of bonding zone 220.

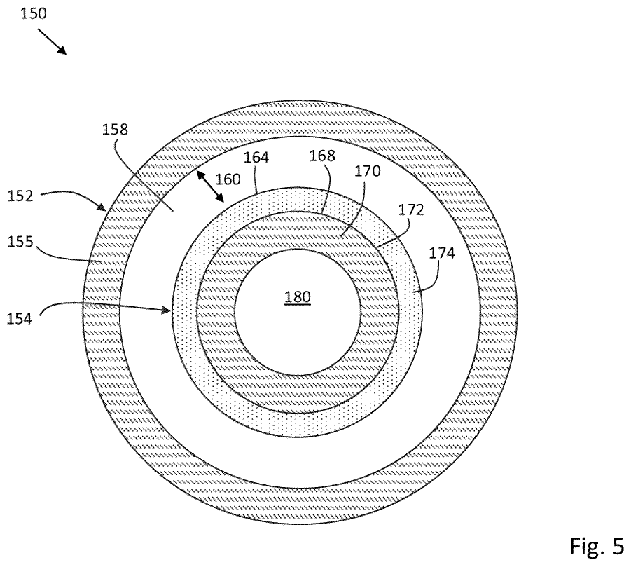

In preferred embodiments, as shown by FIGS. 3 and 5, the platen has a generally cylindrical shape with a height parallel to the z-axis 104 and a circular cross-section in the plane perpendicular to the z-axis 104. The z-axis 104 in this embodiment is coincident with the central axis of the cylindrically shaped platen 100. Socket 108 on the backside 106 is generally circular in cross section and symmetrically located with respect to the z-axis 104 so that the center of the socket 108 is coincident with z-axis 104.

For use in processes such as PVD, CVD, PECVD, APCVD, LPCVD, ALD, MBE, MOCVD, sputtering, TEPVD, RTP, and the like, it is highly desirable that the workpiece 16 is heated. To help accomplish this, one or more different kinds of heating functionality may be incorporated into the workpiece support module 20. As one kind of heating functionality, platen 100 incorporates a heater array 200 incorporating a plurality of heater elements 202 embedded in platen body 116. RF electrode 34 embedded in platen 100 is shown as being deployed above the heater elements 202 but other deployments may be used. As one example, the RF electrode 34 can be deployed below the heater elements 202 as an alternative option.

Each heater element 202 heats a corresponding zone of platen body 116 in which each heater element 202 is located. Each heater element 202 desirably is independently controllable to customize the degree of heating in each associated heating zone, and to adjust the amount of thermal energy delivered to the adjacent portion of the central region 118 of platen 100. In illustrative embodiments, each heater element 202 outputs thermal energy in a manner effective to controllably heat the associated heating zone of platen 100 at a temperature greater than about 80° C., greater than about 100° C., greater than about 200° C., greater than about 300° C., greater than 400° C., or greater than 550° C., such as from 80° C. to about 800° C., or 100° C. to about 800° C., or 300° C. to about 800° C.

These heater elements 202 are connected to a source of electrical power. The flowing electricity resistively heats the heater elements 202. The resulting thermal energy is output by the heater elements 202 to heat the platen 100 and the workpiece 16. For example, each heater element 202 is electrically coupled to associated electrical contacts 124 by wires (not shown). In other embodiments, a particular electrical contact 124 can be coupled to two or more heater elements 202. Wires 122 electrically couple the contacts 124, and hence heater elements 202, to a source of electrical power such as power supply 52.

Even when using an array 200 of heater elements 202, in some embodiments a relative cold spot may still occur in the central region 118 of the platen 100. This could lead to uneven heating of the workpiece, particularly in the colder central region 118. This could impact process uniformity and performance. The relatively cold spot may result at least in part because electrical contacts 124 to the heater elements 202 are made in the central region 118 of the platen 100 so that heating components are not directly deployed in the central region 118.

Accordingly, as a further type of heater functionality to help provide center region heating, heated workpiece support module 20 incorporates a backside heater 206 thermally coupled to the backside 106 of platen 100. Backside heater 206 may be positioned inside the interior volume 180 of pedestal 150 in thermal contact with the backside 106 of platen 100 in a manner effective to help heat the central region 118 of the platen 100. By deploying backside heater 206 against the backside 106 rather than wholly inside platen body 116, the central region 118 of platen 100 remains available to locate electrical contacts 124 of the heater elements 202 to couple the heater elements 202 to a source of electric power (not shown) via wiring 122

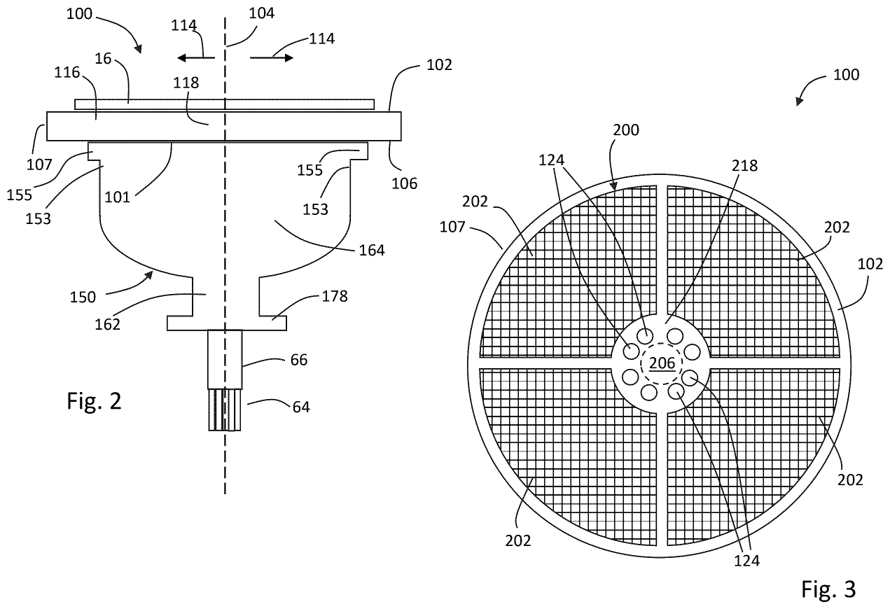

Backside heater 206 is coupled to a source of electric power by wiring 208. Wiring 208 may be constituents of the wires 64 and wire bundle 66 shown in FIG. 2.

Even though heater 206 is at least partially positioned inside the interior volume 180 of pedestal 150, in some embodiments heater 206 may be deemed to be external relative to platen 100 in the sense that heater 206 is not embedded and molded inside platen 100. In a further preferred sense, heater 206 is external in that heater 206 is thermally coupled to platen 100 after platen 100 is formed. In other embodiments, however, some or all of the heater 206 may be embedded in platen 100. Functionally, heater 206 helps to deliver thermal energy to central region 118 of platen 100, and hence, to the central region of workpiece 16 supported on platen 100. In illustrative embodiments, the backside heater 206 outputs thermal energy in a manner effective to help controllably heat the central region 118 at a temperature greater than about 80° C., greater than about 100° C., greater than about 200° C., greater than about 300° C., greater than 400° C., or greater than 550° C., such as from 80° C. to about 800° C., or 100° C. to about 800° C., or 300° C. to about 800° C.

Actuation of the backside heater 206 outputs thermal energy that is transferred to the center region 118 of the platen 100 in a manner effective to controllably heat the central region 118 of the platen 100, and thus a central region of the microelectronic workpiece 16 when the microelectronic workpiece 16 is supported on the platen 100. The heater 206 can be controllably actuated to modulate the delivery of thermal energy. When heating center region 118, the thermal energy output can be reduced if central region 118 is hotter than a desired setpoint temperature or temperature range or increased if central region 118 is cooler than the desired setpoint temperature or temperature range. Heater 206 desirably is electrically coupled to a suitable power supply such as power supply 52 (see FIG. 1). The footprint of the heater 206 is sufficiently small so that there is adequate room available in central region 118 for the contacts 124 and wires 122 associated with the heater elements 202.

Each of heater elements 202 and backside heater 206 is independently controllable relative to each other to allow the heat delivery to each associated heating zone and the central region 118 to be independently adjusted if too cool or too hot. With heater elements 202 and backside heater 206 being independently controllable, the full area of the platen 100, including central region 118, can be controlled to uniformly heat workpiece 16 with excellent precision and stability. Additionally, heater elements 202 and backside heater 206 cooperatively deliver thermal energy to central region 118.

Strategies for incorporating heater arrays and backside heaters into workpiece support module 20 are further described in assignee's co-pending U.S. non-provisional patent application titled CERAMIC HEATER ASSEMBLY WITH INTERNAL AND EXTERNAL HEATING FUNCTIONALITY USEFUL IN THE FABRICATION OF MICROELECTRONIC DEVICES, having Ser. No. 18/609,603, filed Mar. 19, 2024 naming inventor Melvin Verbaas, and having Attorney Docket No. 230109US01 (TEL0002/US). This co-pending U.S. non-provisional patent application is incorporated herein by reference in its entirety for all purposes.

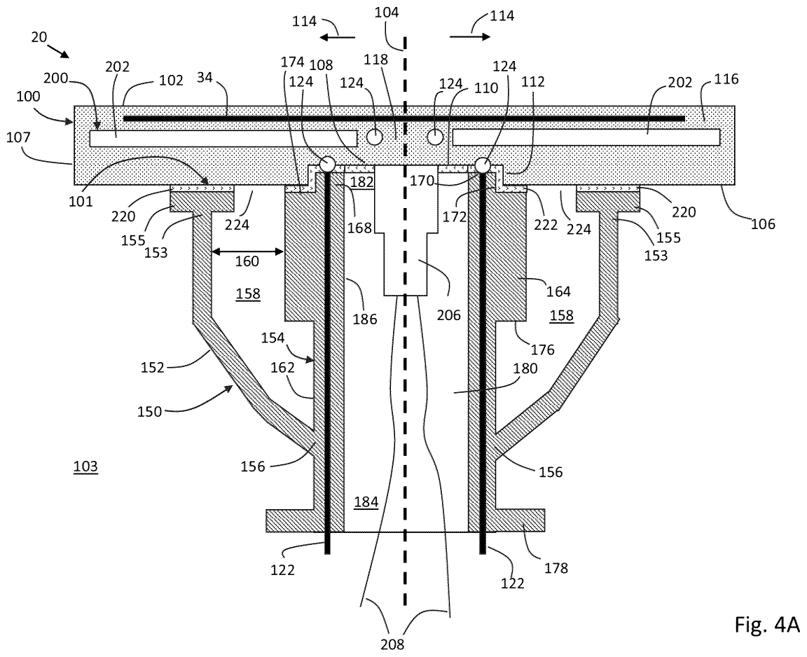

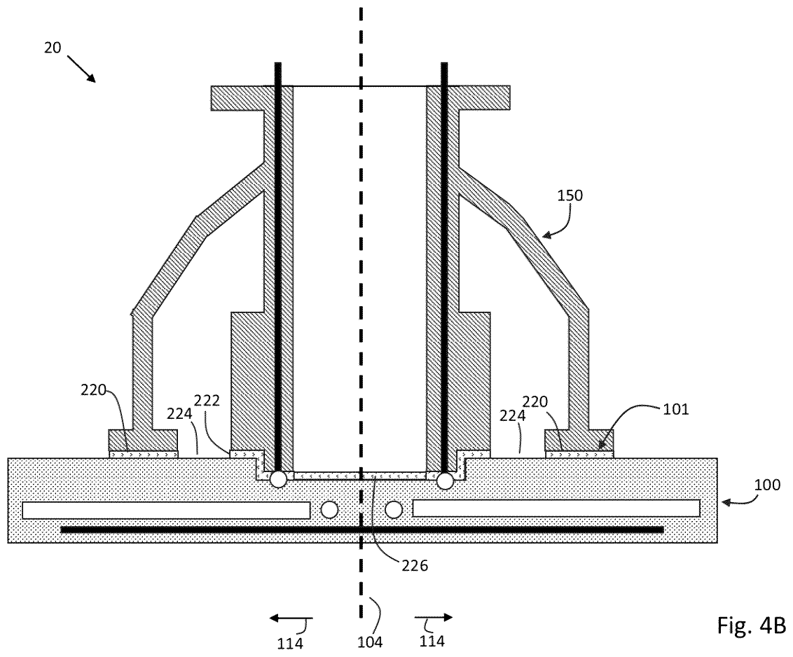

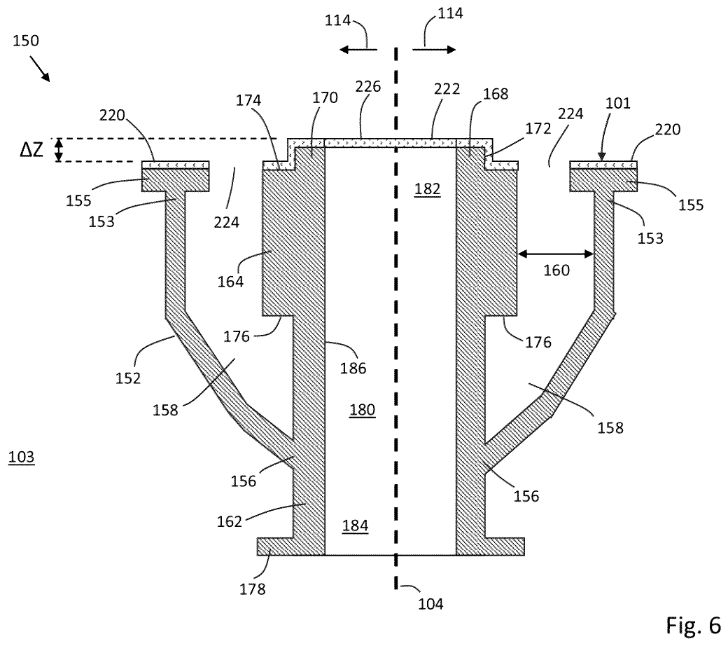

Pedestal 150 includes an outer shroud 152 joined to a generally cylindrical inner central column 154 at a juncture 156. Shroud 152 includes an annular pad 155 at rim 153 proximal to the heated platen 100 Each of the shroud 152 and the central column 154 are attached to the heated platen 100. Pad 155 helps to attach shroud 152 to the backside 106 of platen 100. As seen best in FIGS. 4A, 4B, and 6, the shroud 152 has a cross-section shape that generally corresponds to a tapered hyperboloidal profile that is widest at the rim 153 (which is the end which is attached to the platen 100) and that narrows in a curvilinear, oblate fashion from the rim 153 to the juncture 156. In some embodiments, the hyperboloidal profile may be parabolic. The hyperboloidal profile helps with thermal and mechanical stress relief. In alternative embodiments, the profile may taper in a more linear manner so that the shroud 152 has a conical cross section until meeting the central column 154 at juncture 156. As illustrated, the hyperboloidal profile is outwardly convex relative to the inner central column 154. In some embodiments, the profile may be inwardly convex relative to the inner central column 154, but it is believed that this would be less robust with respect to thermal and mechanical stresses.

Due to the separation of the shroud 152 and inner central column 154 from rim 153 to juncture 156, there is a tapering hollow 158 between the shroud 152 and the central column 154. At each height along the z-axis 104, the hollow has a generally annular-shaped area that is largest in diameter at rim 153 and that becomes increasingly smaller in curvilinear fashion in a direction from rim 153 to juncture 156. Hence, there is a gap 160 between annular pad 155 and the central column 154 proximal to the platen 100. Importantly, this gap 160 and the hollow 158 help to isolate thermal and mechanical stresses and to promote relief of bonding and thermal stresses that might arise between platen 100 and central column 154 and/or pads 155. At the same time, bonding the platen 100 separately to both the central column 154 and the shroud 152 increases the bonding area among the components. The generally hyperboloidal profile of the shroud 152 also facilitates mechanical strength and stress relief. The result is that the quality, strength, and thermal resistance of the bond at bonding interface 101 would be significantly improved.

Inner central column 154 generally includes a cylindrical shaft portion 162 having an enlarged body portion 164 at a first end and a lower flange 178 at a second end. The body portion 164 has an annular boss 168 that projects outward from pedestal 150 and into the socket 108 of platen 100. The annular boss 168 has an annular end face 170 and a cylindrical sidewall 172. Body portion 164 extends outward from annular boss 168 to provide an annular upper shoulder 174. In this embodiment, shoulder 174 is bonded to the backside 106 of platen 100 by a portion of the bonding interface 101. Body portion 164 extends outward from the shaft portion 162 to have an annular lower shoulder 176.

In this embodiment, inner central column 154 is hollow, having an interior sidewall 186 that defines interior volume 180 having an upper end 182 and a lower end 184. The interior volume 180 serves as an interior passageway that provides an egress from the passageway to the backside 106 of platen 100. Thus, for example, the backside heater 206 is housed inside interior volume 180 when thermally coupled to the central region 118 of platen 100 via socket 108 on the on the backside 106. Interior volume 180 also is useful for housing additional components and for providing a conduit for electrical wiring. In some embodiments, wiring 122 may be embedded in the structure of pedestal 150 and/or platen 100. For purposes of illustration, FIG. 2 schematically shows how wires 64 in a wiring bundle 66 can be fed through pedestal 150 and then connected to other electrical components (not shown in FIG. 2).

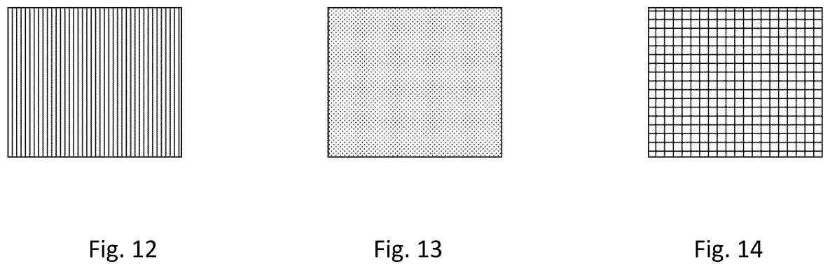

Flange 178 is used to help attach pedestal 150 to lifting apparatus 22. Pad 155, annular boss 168, and upper shoulder 174 have surfaces that are used to bond the pedestal 150 to the backside 106 of platen 100. The mating surfaces of the platen 100 and/or pedestal 150 that are bonded to each other may be textured or otherwise surface modified in order to enhance the strength of bonding. For example, FIGS. 12, 13, and 14 schematically show how such mating surfaces may be textured to improve bonding. FIG. 12 shows how a bonding surface may be grooved and/or ribbed. FIG. 13 shows how a bonding surface may include a plurality of dimples and/or protuberances to enhance bonding. FIG. 14 shows how a crisscross network of grooves and/or ribs may be used to enhance bonding.

The platen 100 and the pedestal 150 are attached to each other via bonding interface 101 in a manner so that the central axes of each are aligned to form a common, central z-axis 104. The radially outward direction from the central z-axis 104 is shown schematically by arrows 114. Thus, for example, outer periphery 107 of platen 100 is radially outward from center z-axis 104.

As shown best in FIGS. 4 and 6, the bonding interface 101 includes a plurality of separated bonding zones 220 and 222 to attach the platen 100 and pedestal 150 to each other. The bonding zones are configured to help create a vacuum tight seal between the platen 100 and the pedestal 150. The first bonding zone 220 attaches the annular pad 155 of shroud 152 to the backside 106 of the platen 100. Desirably, the first bonding zone 220 surrounds the interior volume 180 and attaches the platen 100 to the pedestal 150 relatively distal from the interior volume 180. The second bonding zone 222 attaches the inner central column 154 to the backside 106 of platen 100 in a manner such that the annular boss 168 fits into socket 108 of platen 100 while an annular portion of platen backside 106 proximal to socket 108 is supported on shoulder 174 of pedestal body 164. An annular portion of the bonding zone 222 bonds socket floor 110 to the end face 170 of annular boss 168. A generally cylindrical portion of the bonding zone 222 bonds the boss sidewall 172 to the sidewall 112 of the socket 108. Another annular portion of the bonding zone 222 bonds the backside 106 of platen 100 to the shoulder 174. Thus, the bonding zone 222 provides a continuous, bonding interface that surrounds the interior volume 180 and attaches the pedestal 150 to the platen 100 relatively proximal to the interior volume 180.

A bond-free zone 224 separates the bonding zones 220 and 222 so that the bonding zones 220 and 222 are separate and isolated from each other. This isolation and separation helps to prevent thermal and mechanical stresses from being transmitted between the bonding zones 220 and 222. This isolation and separation helps to make the bonding interface 101 more robust against thermal and mechanical stresses. This in turn helps to maintain a vacuum tight seal between platen 100 and pedestal 150.

Another feature of bonding interface 101 that helps to relieve thermal and mechanical stresses is that at least a portion of the bonding zone 220 is at a different z-height on z-axis 104 than at least a portion of the bonding zone 222. This is shown best in FIG. 6. FIG. 6 shows how there is a z-height difference AZ between the bonding zone 220 and the annular bonding portion 226 of bonding zone 222. Deploying portions of the bonding interface 101 at different z-heights relative to z-axis 104 is another strategy that helps to relieve thermal and mechanical stresses in the bonding interface 101. The combination of using separate, isolated bonding zones 220 and 222 and deploying at least portions of the bonding zones 220 and 222 at different z-heights is particularly effective at relieving thermal and mechanical bonding stresses and promoting a vacuum tight seal. Thus, a vacuum established in process chamber 14 (FIG. 1) is established and maintained in isolation from the interior volume 180. If a vacuum tight seal is not maintained, material from the ambient and/or from the interior volume 180 could leak into process chamber 14 and adversely impact process performance.

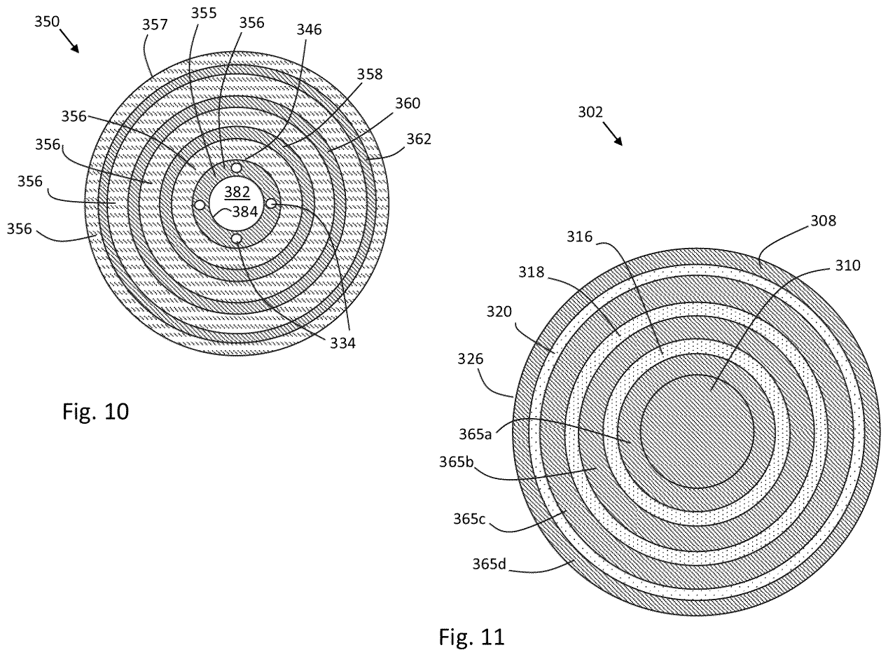

FIG. 4A shows the typical orientation of heated workpiece support module 20 during a process treatment. In this orientation, the platen 100 and pedestal 150 or oriented so that the platen 100 is supported on the pedestal 150, which is below the platen 100. This may be referred to as a “right side up” orientation. FIG. 4B shows an alternative orientation of platen 100 and pedestal 150 that is useful when bonding platen 100 to pedestal 150. This may be referred to as the “upside down” orientation. Assembly in the upside down orientation facilitates more precise deployment of bonding media in the desired bonding zones. In the practice of the present invention, the upside down orientation is useful with respect to the bonding of any platen and pedestal in any embodiments of the heated workpiece support modules of the present invention, including but not limited to those embodiments shown in FIGS. 1 through 14.

The platen 100 and pedestal 150 of heated workpiece support module 20 are engineered to withstand the rigors of high-temperature processing environments typically encountered in semiconductor fabrication processes such as PVD, CVD, PECVD, APCVD, LPCVD, ALD, MBE, MOCVD, sputtering, TEPVD, RTP, and the like. Given the thermal and mechanical demands placed on the assembly, materials selected for construction exhibit desired thermal conductivity, thermal shock resistance, and chemical stability. Ceramic materials, known for their robust thermal and mechanical properties, are well-suited for this application.

Accordingly, each of platen 100 and pedestal 150 independently comprises one or more ceramic materials, which may be the same or different. The selection of at least one ceramic as the material of choice for each of the platen 100 and pedestal 150 stems from the ability of ceramic materials to maintain structural integrity and performance characteristics at elevated temperatures, which can significantly exceed the threshold levels of conventional materials. Furthermore, ceramics exhibit excellent resistance to corrosion and wear, ensuring longevity and reliability of the wafer support mechanism in a chemically reactive and abrasive processing environment.

Among the ceramics, each of the platen 100 and pedestal 150 preferably is made from materials including at least aluminum nitride (AIN). Aluminum nitride is a preferred material due to its thermal stability as well as its excellent thermal conductivity. The thermal conductivity characteristics help provide efficient transfer of heat to the wafer. This in turn helps to provide uniform temperature distribution across the platen top side 102 and hence across workpiece 16.

Each of platen 100 and pedestal 150 can be made from one or more other ceramic materials, if desired, that may be used with aluminum nitride or as alternative(s) to aluminum nitride. Examples of other suitable ceramic materials include one or more of silicon carbide, silicon nitride, boron nitride, zirconium dioxide, and/or alumina. Silicon Carbide (SiC) is known for its high thermal conductivity and excellent mechanical strength. Silicon carbide is also highly resistant to thermal shock, making it suitable for fluctuating temperature conditions. Silicon Nitride (Si₃N₄) offers exceptional thermal stability and resistance to thermal shock, alongside significant mechanical toughness. This makes silicon nitride suitable for demanding processing environments. Boron Nitride (BN) is known for its high thermal conductivity and electrical insulation properties. Boron nitride is particularly useful in applications requiring both thermal management and electrical isolation. Zirconium Dioxide (ZrO₂), or Zirconia exhibits high temperature resistance and thermal insulation properties, along with a low thermal conductivity. This makes zirconia suitable for applications requiring thermal barriers. Alumina (Al₂O₃) provides excellent electrical insulation and resistance to corrosion and wear, making it a versatile choice for various components of the platen 100 and/or pedestal 150.

The fabrication of the ceramic components of heated workpiece support module 20, such as platen 100, pedestal 150, for use in the context of high-temperature semiconductor processing applications such as PVD, CVD, PECVD, APCVD, LPCVD, ALD, MBE, MOCVD, sputtering, TEPVD, RTP, and the like, preferably involves a manufacturing process known as sintering. This process converts powdered ceramic materials into a solid, dense structure through the application of heat and pressure. A first step in a typical sintering process involves the preparation of the ceramic powder. This powder can be made from a variety of ceramic materials, such as aluminum nitride, silicon carbide, silicon nitride, boron nitride, zirconia, and/or alumina, depending on the desired properties of the final product. The powder may be mixed with a binder or other additives to aid in the sintering process and improve the mechanical properties of the end product.

Once the ceramic powder is prepared, the powder is molded or shaped into the desired form of the component, such as platen 100 or pedestal 150. This shaping can be achieved through various methods, including dry pressing, isostatic pressing, or extrusion. The choice of shaping method depends on the complexity of the component's design and the specific properties required. In dry pressing, the powder is compressed in a rigid mold under high pressure. Isostatic pressing involves applying pressure uniformly in all directions using a fluid medium, which is suitable for achieving high-density and uniform parts. Extrusion, on the other hand, is useful for creating components with constant cross-sectional profiles.

After shaping, the ceramic parts undergo a sintering process. Sintering involves heating and shaping the powder in a furnace to a temperature typically below the melting point of the main component but high enough to facilitate diffusion and bonding among the powder particles. This heat treatment causes the particles to bond together, densify, and reduce or eliminate porosity, resulting in a solid, dense ceramic component. The sintering atmosphere (which in illustrative modes of practice can be vacuum, inert, oxidizing, or reducing) and the specific temperature profile are carefully controlled to facilitate development of desired material properties and to prevent defects.

Following sintering, the ceramic components optionally may undergo one or more post-sintering treatments to achieve the desired surface finish, dimensional accuracy, or mechanical properties. These treatments can include machining, grinding, polishing, and additional heat treatments. For example, machining or grinding may be required to achieve tight dimensional tolerances or specific surface textures. Additional heat treatments can be used to relieve internal stresses or to modify the microstructure for improved mechanical properties.

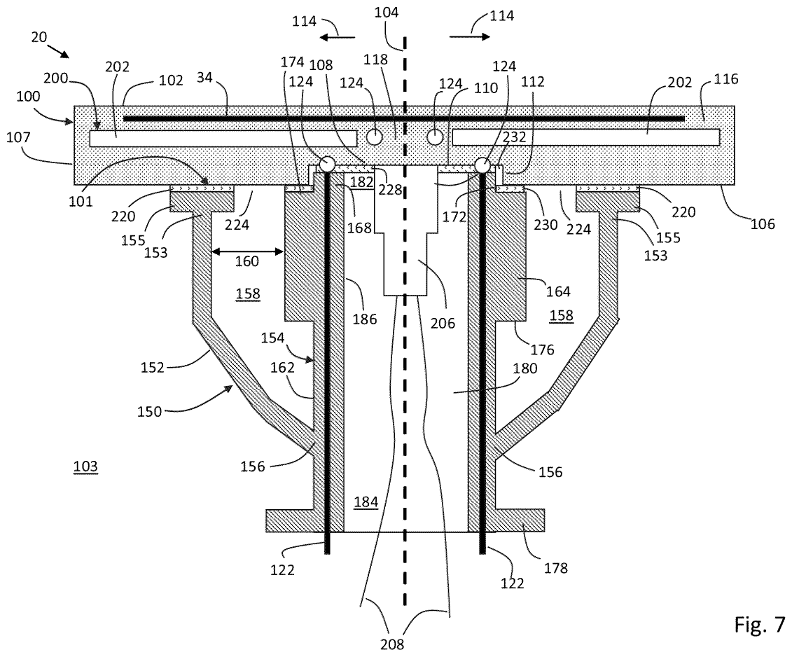

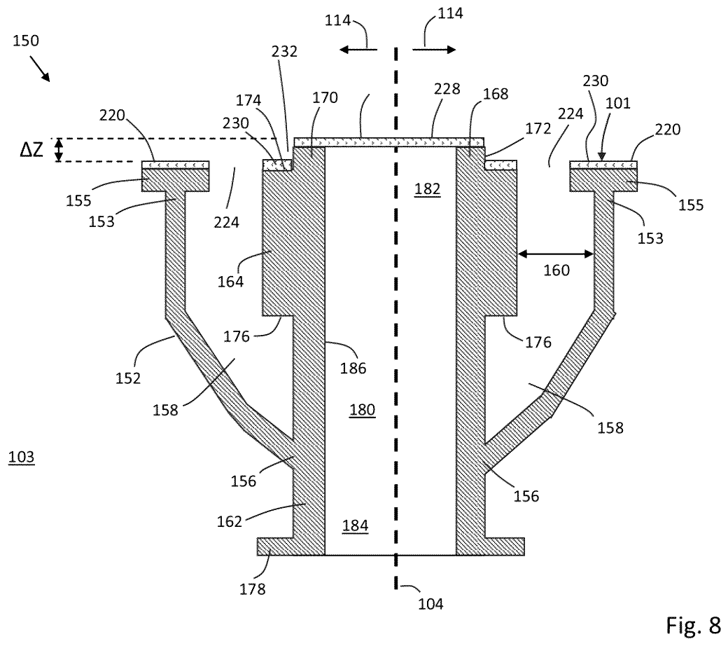

FIGS. 7 and 8 illustrate an alternative embodiment for providing bonding interface 101 in the heated workpiece support module 20 of FIGS. 1 through 6. Heated workpiece support module 20 in FIG. 7 is identical to the heated workpiece support module 20 of FIGS. 1 through 6 except that bonding zones 228 and 230 are used in FIG. 7 instead of the bonding zone 222. Bonding zone 228 is annularly shaped and attaches shoulder 174 of inner central column 154 to the backside 106 of platen 100 proximal to interior volume 180. Bonding zone 230 is annularly shaped and attaches the end face 170 of annular boss 168 to the socket floor 110 of socket 108 on the backside 106 of platen 100. Bonding zone 228 is separated and isolated from bonding zone 230. An annular, cylindrically shaped gap 232 is between the bonding zones 228 and 230. The gap 232 extends from the bonding zone 228 to the bonding zone 230 in a vertical direction parallel to the z-axis 104. As shown in FIG. 8, bonding zone 230 is at a different z-height AZ than bonding zones 220 and 228. This embodiment of bonding interface 101 helps to relieve thermal and mechanical stresses between platen 100 and pedestal 150, which in turn helps to maintain a vacuum tight seal between the platen 100 and pedestal 150 at bonding interface 101.

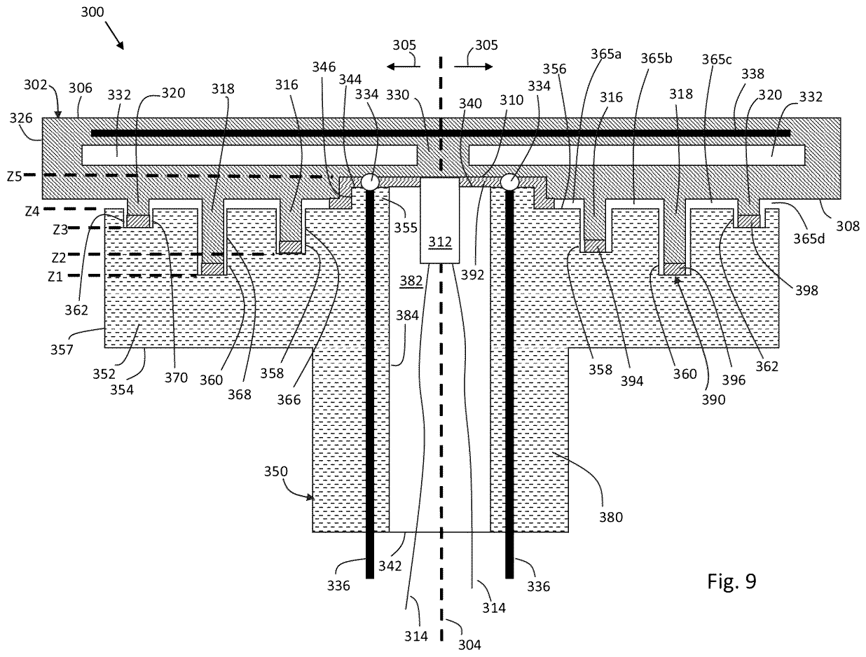

FIGS. 9, 10, and 11 show an alternative embodiment of a heated workpiece support module 300 useful in the apparatus 10 of FIG. 1 in place of heated workpiece support module 20. Heated workpiece support module 300 generally includes a platen 302 supported on a pedestal 350. The platen 302 and pedestal 350 are attached to each other by a bonding interface 390 including separate and isolated bonding zones 392, 394, 396, and 398. The mating structures of platen 302 and the pedestal 350 as well as features of the bonding interface 390 help to relieve thermal and mechanical stresses between the platen 302 and the pedestal 350 and to help create a vacuum tight seal between the platen 302 and the pedestal 350.

The platen 302 and the pedestal 350 are attached to each other via interface 390 in a manner so that the central axes of each are aligned to form a common, central z-axis 304. The radially outward direction from the central z-axis 304 is shown schematically by arrows 305. Thus, for example, outer periphery 107 of platen 100 is radially outward from center z-axis 104.

Platen 302 has a top 306, a backside 308, an outer periphery 326 and a center region 330. A microelectronic workpiece (not shown) would be supported over the top 306 during treatments. A plurality of heater elements 332 are embedded in the platen 302 to heat corresponding heating zones of platen 302. The heater elements 332 are electrically coupled to electrical connects 334. The electrical connects 334 are connected to a source of electrical power (not shown) by wiring 336. The electrical power causes heater elements 332 to resistively heat and deliver thermal energy to the workpiece 16. Lower RF electrode 338 is embedded in platen 302.

Backside 308 includes several features to help couple platen 302 to pedestal 350. These features include centrally located socket 310 symmetrically positioned around z-axis 304. Additionally, backside 308 includes at least one ring that projects outward away from backside 308 from one or more locations radially outward from socket 310. For purposes of illustration, a plurality of concentric, annular rings 316, 318, and 320 are shown. The rings 316, 318, and 320 have different heights Z1, Z2, and Z3 relative to the z-axis 304. Each of the rings 316, 318, and 320 may have different widths from the inner ring face to the outer ring face as well. For purposes of illustration, rings 316, 318, and 320 are shown as having the same width from the inner face to the outer face.

Backside heater 312 is thermally coupled to the socket 310 in a manner effective to help deliver thermal energy to the center region 330 of platen 302. Heater elements 332 also help to deliver thermal energy to the center region 330. Backside heater 312 is coupled to a source of electrical power (not shown) by wiring 314. Each of the heater elements 332 and the backside heater 312 are independently controllable with respect to delivery of thermal energy to heat platen 302 and, hence, the workpiece 16.

Pedestal 350 includes body 352 at an upper end of column 380. Body includes lower face 354, upper face 356, and sidewall 357. Column 380 extends downward from the lower face 354.

Pedestal 350 is hollow. Interior sidewall 384 defines an interior volume 382 that provides an egress to the backside 308 of platen 302. For purposes of illustration, backside heater 312 is housed in the interior volume 382. Wiring 314 is fed to the backside heater 312 through the egress provided by the interior volume 382.

An annular boss 355 extends upward from a central region of body 352. Annular boss 355 includes a first inlet 340 providing an egress into interior volume 382, and column 380 includes a second inlet 342 providing an additional egress into interior volume 382. Boss 355 includes upper face 344 and sidewall 346.

One or more annular sockets, preferably a plurality of annular sockets are formed in the upper face 356 of the body 352. For purposes of illustration, body 352 includes a trio of annular sockets 358, 360, and 362 that extend from upper face 356 downward into the body 352. The sockets are numbered and sized to receive corresponding rings 316, 318, and 320 of platen 302. When platen 302 is mounted onto pedestal 350, the boss 355 of pedestal 350 fits into socket 310 of platen 302, and rings 316, 318, and 320 fit into and are housed in annular sockets 358, 360, and 362, respectively.

Each of the rings 316, 318, and 320 has a width that is undersized relative to the corresponding annular socket 358, 360, or 362, respectively. This helps to provide gaps 366, 368, and 370 between the sides of the rings and the sides of the sockets when the bottoms of the rings 316, 318, and 320 are bonded to the bottoms of the corresponding sockets 358, 360, or 362, respectively. It is believed that gap widths from 0.05 mm to 2 mm, preferably 0.05 mm to 1 mm, more preferably 0.05 mm to 0.5 mm would be suitable. In an illustrative embodiment, the width of the gaps between the rings 316, 318, and 320 and sockets 358, 360, or 362 is about 0.1 mm. Desirably, at least a portion of the sides of the rings 316, 318, and 320 are not bonded to the adjacent side portions of the sockets 358, 360, or 362 so that gaps include bond free zones between the rings and sockets. The length of the rings 316, 318, and 320, as shown, may be longer than the depth of the corresponding sockets 358, 360, or 362, respectively, so that the platen 302 stands proud of the pedestal body 352 except in the areas where the rings 316, 318, and 320 are bonded to the sockets 358, 360, and 362 and where the platen socket 310 and adjacent area of the platen backside 308 are bonded to the pedestal boss 355 and adjacent annular area of top 356 of the pedestal 350. This provides annular gaps 365a, 365b, 365c and 365d between the platen 302 and the pedestal 350 that helps to relieve and avoid mechanical stresses between platen 302 and pedestal 350.

FIG. 9 best shows how bonding interface 390 includes a plurality of bonding zones that are separated and isolated from each other. Bonding zone 392 couples socket 310 to the annular boss 355 and adjacent areas of the top 356 of pedestal 350. Radially outward from bonding zone 392, bonding zone 394 attaches the bottom of ring 316 to the bottom of socket 358. A bond free zone exists in annular gap 365a. Radially outward from bonding zone 394, bonding zone 396 attaches the bottom of ring 318 to the bottom of socket 360. A bond free zone exists in annular gap 365b. Radially outward from bonding zone 396, a bonding zone 398 attaches the bottom of ring 320 to the bottom of socket 362. A bond free zone exits in the annular gap 365c. A further bond free zone exists in gap 365d radially outward from bonding zone 398. Each of bonding zones 392, 394, 396, and 398 include bonding zone portions at different z-heights relative to at least one of the other bonding zones. In this embodiment, each of bonding zones 392, 394, 396, and 398 include portions at a different z-heights z1, z2, z3, z4, and z5 relative to the other bonding zones. Using separate, isolated bonding zones 392, 394, 396, and 398 in combination with bond free zones and different z-height deployment results in a vacuum tight connection between platen 302 and pedestal 350 that is resistant to mechanical and thermal stresses. Thus, a vacuum established in process chamber 14 (FIG. 1) is established and maintained in isolation from the interior volume 382. If a vacuum tight seal is not maintained, material from the ambient and/or from the interior volume 382 could leak into process chamber 14 and adversely impact process performance.

FIG. 9 shows how deployment of bonding media in the vertical gaps 366, 368, and 370 is avoided. The upside down orientation described above with respect to FIG. 6B is particularly useful when assembling platen 302 and pedestal 350 in order to be able to precisely deploy bonding media at the bottom of sockets 358, 360, and 362 and avoid causing undue amounts of bonding media to glue the vertical gaps 366, 368, and 370. If these gaps 366, 368, and 370 were unduly filled with bonding media, the ability of the structure to relieve and dissipate thermal and mechanical stresses could be reduced. There would be an increased risk that bonding interface 390 or the components themselves could crack, rupture, or otherwise degrade. The bonding strategy seen best in FIG. 9 helps to isolate such thermal and mechanical stresses and would dramatically reduce the tendency of mechanical and thermal stresses to propagate through pedestal 350 and thereby cause undue damage.

To summarize the embodiment of the heated workpiece module 300 of FIGS. 9 through 11, the heated workpiece support module 300 is useful in apparatus 10 of FIG. 1 and comprises a platen 302, over which the workpiece 16 is supported during a treatment. The platen 302 is supported on pedestal 350. Pedestal 350 provides stable and precise support for positioning platen 302 within the process chamber 14. The platen 302 is characterized by a wide, thick table-like structure housing internal heating elements 332 and the lower RF electrode 338. The pedestal 350, generally cylindrical in this illustrative embodiment although other geometries may be used, includes a wider upper body 352 and a narrower column 380 below, contributing to the overall stability and functionality of the support system.

The principles of the present invention provides a coupling strategy between the platen 302 and the pedestal 350 that helps to ensure both structural integrity and ease of assembly. The backside 308 of the platen 302 features a centrally located socket 310 designed to receive a corresponding boss 355 located on the top of the pedestal body 352. This central boss-and-socket arrangement provides a first point of attachment, helping to align the platen 302 securely on the pedestal 352. In addition to this central coupling, a trio of concentric, annular rings 316, 318, and 320 project downward from the backside 308 of the platen 302. These rings 316, 318, and 320 fit with a loose fit into corresponding annular sockets 358, 360, and 362 formed in the top surface 356 of the pedestal body 352, providing additional support and stability and further helping to ease and guide assembly.

This deployment of the sockets 358, 360, and 362 in the body 355 of the pedestal 350, rather than in the platen 302, offers several advantages. By locating the sockets 358, 360, and 362 in the pedestal body 352, the design preserves the integrity of the platen's interior, maintaining sufficient volume in the platen 302 for the heater elements 332 and the RF electrode 338. This configuration minimizes any potential disruption to the thermal and electrical pathways within the platen 302. This also facilitates more uniform heating of the platen 302. Collectively, the configuration of sockets and rings according to this embodiment enhances the overall performance of the heated workpiece support module 300 during a treatment such as a plasma treatment. Additionally, the concentric annular rings 358, 360, and 362 help to provide a robust and reliable mechanical connection, distributing mechanical and thermal loads more evenly across the platen 302 and pedestal 350, helping to reduce the likelihood of mechanical stress or misalignment during assembly or operation. This design helps to ensure that the heated workpiece support module 300 maintains its stability and precision throughout a process, thus contributing to achieving consistent and high-quality results in the treatment of microelectronic workpieces such as workpiece 16 (FIG. 1).

All patents, patent applications, and publications cited herein are incorporated herein by reference in their respective entities for all purposes. The foregoing detailed description has been given for clarity of understanding only. No unnecessary limitations are to be understood therefrom. Various modifications and alterations of this disclosure will become apparent to those skilled in the art without departing from the scope and principles of this disclosure, and it should be understood that this disclosure is not to be unduly limited to the illustrative embodiments set forth hereinabove.

What is claimed is:

1. A heated workpiece support module useful to support a microelectronic workpiece in a process chamber during a process, said heated workpiece support module having a z-axis and comprising:
a) a heated platen having a top and a backside, wherein the workpiece is supported over the top of the platen during the process; and
b) a hollow pedestal, wherein:
the hollow pedestal is attached to the backside of the heated platen;
the hollow pedestal contains an interior volume;
the hollow pedestal is attached to the heated platen by a plurality of bonding interfaces that are configured to create a vacuum tight seal between the heated platen and the hollow pedestal, said plurality of bonding interfaces including:
i) a first, continuous bonding zone that surrounds the interior volume and that attaches the heated platen to the hollow pedestal proximal to the interior volume; and
ii) a second, independent, separate and continuous bonding zone that surrounds the interior volume and that attaches the heated platen to the hollow pedestal distal from the interior volume, wherein at least a major portion of the second, independent, separate, and continuous bonding zone is separated from the first, continuous bonding zone by a bond-free zone; and
wherein at least a first interface portion of the first, continuous bonding zone is at a different z-height on the z-axis relative to at least a first interface portion of the second, continuous bonding zone.

2. The heated workpiece support module of claim 1, wherein the heated platen is heated to a temperature greater than 100° C.

3. The heated workpiece support module of claim 1, wherein the heated platen is heated to a temperature in the range from about 300° C. to about 800° C.

4. The heated workpiece support module of claim 1, wherein the heated platen and the hollow pedestal each independently comprises one or more ceramic materials.

5. The heated workpiece support module of claim 1, wherein the heated platen and the hollow pedestal each comprises aluminum nitride.

6. The heated workpiece support module of claim 1, wherein the hollow pedestal comprises an outer shroud joined to a generally cylindrical central column at a juncture.

7. The heated workpiece support module of claim 6, wherein each of the outer shroud and the generally cylindrical central column are attached to the heated platen such that the first, continuous bonding zone attaches the generally cylindrical central column to the heated platen and the second, independent, separate and continuous bonding zone attaches the outer shroud to the heated platen.

8. The heated workpiece support module of claim 6, wherein the outer shroud has a hyperboloidal profile.

9. The heated workpiece support module of claim 6, wherein the outer shroud has a rim proximal to the heated platen, and wherein the outer shroud tapers in a direction from the rim to the juncture.

10. The heated workpiece support module of claim 1, wherein the heated platen includes a socket and the pedestal includes a boss, and wherein the boss fits into the socket.

11. The heated workpiece support module of claim 1, wherein the heated platen includes a plurality of annular rings and the pedestal includes a plurality of corresponding annular sockets, and wherein the annular rings are housed in the corresponding annular sockets.

12. The heated workpiece support module of claim 11, wherein the plurality of annular rings includes at least two annular rings and wherein the two of the annular rings have different heights relative to a z-axis.

13. The heated workpiece support module of claim 11, wherein the plurality of annular rings includes at least three annular rings and wherein at least three of the annular rings have different heights relative to a z-axis.

14. The heated workpiece module of claim 12, wherein the plurality of annular sockets includes at least two annular sockets, and wherein the two annular sockets have a different depth relative to a z-axis corresponding to the heights of the annular rings housed in the annular sockets.

15. The heated workpiece module of claim 13, wherein the plurality of annular sockets includes at least three annular sockets, and wherein the three annular sockets have a different depth relative to a z-axis corresponding to the heights of the annular rings housed in the annular sockets.

16. The heated workpiece module of claim 11, wherein each of the annular rings has a bottom and a side, wherein each of the annular sockets has a bottom and a side, wherein the annular rings are undersized such that there is an annular gap between the sides of the annular rings and the sides of the corresponding sockets, and wherein the bottoms of the annular rings are bonded to the bottoms of the annular sockets such that at least a portion of the gaps between the annular rings and the annular sockets are bond-free zones.

17. The heated workpiece module of claim 1, wherein the heated platen includes at least one ring projecting from the backside of the heated platen, wherein the hollow pedestal includes at least one socket in an upper face of the pedestal, and wherein the ring fits into the socket to help couple the heated platen to the pedestal.

18. A heated workpiece support module useful to support a microelectronic workpiece during a process, said heated workpiece support module having a z-axis and comprising:
a) a heated platen having a top and a backside, wherein the workpiece is supported over the top of the platen during the process, wherein the heated platen comprises at least one annular ring projecting from the backside, and wherein the ring has a bottom; and
b) a hollow pedestal having a top, wherein the top comprises at least one annular socket having a bottom sized and positioned to receive the annular ring of the heated platen, and, wherein:
the hollow pedestal is attached to the backside of the heated platen;
the hollow pedestal contains an interior volume;
the hollow pedestal is attached to the heated platen by a plurality of bonding interfaces that are configured to create a vacuum tight seal between the heated platen and the hollow pedestal, said plurality of bonding interfaces including:
i) a first bonding zone that surrounds the interior volume and that attaches the heated platen to the hollow pedestal proximal to the interior volume; and;
ii) a second, annular bonding zone that is independent and separate from the first annular bonding zone and that bonds the bottom of the ring to the bottom of the socket in a manner such that a z-axis, gap is provided between the ring and the socket, wherein the gap has a height dimension extending along the z-axis.

19. An apparatus useful to subject a microelectronic workpiece to a process, said apparatus comprising:
a) a housing defining a process chamber;
b) a heated workpiece support module having a z-axis and comprising:
1) a heated platen having a top and a backside, wherein the workpiece is supported over the top of the platen during the process;
2) a hollow pedestal, wherein:
i) the hollow pedestal is attached to the backside of the heated platen;
ii) the hollow pedestal contains an interior volume;
iii) the hollow pedestal is attached to the heated platen by a plurality of bonding interfaces that are configured to create a vacuum tight seal between the heated platen and the hollow pedestal, said plurality of bonding interfaces including a first, continuous bonding zone that surrounds the interior passageway and that attaches the heated platen to the hollow pedestal proximal to the interior passageway; and a second, independent, separate and continuous bonding zone that surrounds the interior volume and that attaches the heated platen to the hollow pedestal distal from the interior passageway, wherein at least a major portion of the second, independent, separate, and continuous bonding zone is separated from the first, continuous bonding zone by a bond-free zone; and
wherein at least a first interface portion of the first, continuous bonding zone is at a different z-height on the z-axis relative to at least a first interface portion of the second, continuous bonding zone.

20. An apparatus useful to subject a microelectronic workpiece to a process, said apparatus comprising:
a) a housing defining a process chamber;
b) a heated workpiece support module having a z-axis and comprising:
1) a heated platen having a top and a backside, wherein the workpiece is supported over the top of the platen during the process, wherein the heated platen comprises at least one annular ring projecting from the backside, and wherein the ring has a bottom;
2) a hollow pedestal having a top, wherein the top comprises at least one annular socket having a bottom sized and positioned to receive the annular ring of the heated platen, and, wherein:
i) the hollow pedestal is attached to the backside of the heated platen;
ii) the hollow pedestal contains an interior volume; and
wherein the hollow pedestal is attached to the heated platen by a plurality of bonding interfaces that are configured to create a vacuum tight seal between the heated platen and the hollow pedestal, said plurality of bonding interfaces including a first bonding zone that surrounds the interior passageway and that attaches the heated platen to the hollow pedestal proximal to the interior passageway; and a second, annular bonding interface that is independent and separate from the first annular bonding interface and that bonds the bottom of the ring to the bottom of the socket in a manner such that a z-axis, gap is provided between the ring and the socket, wherein the gap has a height dimension extending along the z-axis.

21. A method of processing a microelectronic workpiece, comprising the steps of:
a) supporting the microelectronic workpiece on the heated platen of the heated workpiece support module of the apparatus of claim 19; and
b) while the microelectronic workpiece is supported on the heated platen, subjecting the microelectronic workpiece to a process.
